(19) United States
(12) Patent Application Publication
(10) Pub. No.: US 2010/0151147 A1
(43) Pub. Date: Jun. 17, 2010

(54) METAL PATTERN FORMATION METHOD AND METAL PATTERN FORMATON SYSTEM

(76) Inventors: Li-Jiuan Chen, Taoyuan County (TW); Chien-Ho Huang, Taipei City (TW); Hsiou-Jeng Shy, Sanchong City (TW); Shang-Wano Yeh, Taoyuan County (TW); Ching-Yu Tso, Taipei City (TW)

Correspondence Address: Dr. BANGER SHIA;Patent Office of Bang Shia, 102 Lindencrest Ct, Sugar Land, TX, 77479-5201, US

(21) Appl. No.: 12/334,461

(22) Filed: Dec. 13, 2008

(51) Int. Cl. B05D 3/06; C23C 16/00; B05C 11/00

(52) U.S. Cl. 427/557; 427/250; 118/46

(57) ABSTRACT

The invention discloses a metal pattern formation method including the following steps. At first, an organic liquid is printed on a substrate to form a base pattern. Afterward, a metal is evaporated to generate several metal particles for covering the printed substrate. At last, the substrate is heated to vaporize the base pattern, and the metal particles adhered to the substrate forms a metal pattern complementary to the base pattern.

### BACKGROUND OF THE INVENTION

1. Field of the Invention

The invention relates to a metal pattern formation method and a metal pattern formation system and, more particularly, to a metal pattern formation method and a metal pattern formation system utilizing an organic liquid printing technique and a metal evaporating technique.

2. Description of the Prior Art

Several methods of forming a metal pattern are widespread in modern industries, e.g. dry film, photoresist and etching procedures. However, said procedures of prior art are considerably complex and costly. If there is a procedure with convenience and highly cost-efficiency, it may replace present procedures and develop some new applications.

In general, a basic procedure of forming a precise metal pattern is to print conductive metallic ink directly. However, the conductive metallic ink is costly and the metal pattern under this procedure is uneven. Therefore, it develops a procedure utilizing an organic liquid printing technique and a metal evaporating technique for metal pattern formation. For example, to print the letter “A”, it can be done by printing a base pattern of a hollow letter “A” with the organic liquid at first. In other words, the printing of the organic liquid is used for covering the region of the substrate which needs not to be metalized and showing the region of the substrate to be metalized. Afterward, it is to utilize the metal evaporating technique for generating a plurality of metal particles (metal steam), which is used for covering the substrate. Because the region of the letter “A” on the substrate is hollow without the organic liquid, the metal particles attach onto the hollow region of the substrate only. At last, the region covered by the metal particles forms a metal pattern shaped in the letter “A”.

In the procedure utilizing the organic liquid printing technique and the metal evaporating technique, it is very important to select a proper organic liquid. If the vaporizing speed of the organic liquid is too fast, the organic liquid will vanish before the metal particles covering the hollow region entirely, so that the organic liquid will lose shielding function and the metal pattern can not be completed. On the other hand, if the vaporizing speed of the organic liquid is too slow, the organic liquid can not be vaporized quick enough after the metal evaporation, so that the organic liquid left will have swelling reaction with the substrate. The swelling reaction limits applications of the procedure in food packing industry, and is also an obstacle in lamination of the product packing.

The procedure needs to select the organic liquid with the proper vaporizing speed, and therefore limits the usability of the procedure. The vaporizing speed of the organic liquid is related not only to the characteristic of itself but also to the vacuum condition of the metal evaporating space and the evaporating temperature. Besides, the adhesive strength between the substrate and the organic liquid, and even the thickness and shape of the pattern do matter the vaporizing speed of the organic liquid. That is to say, to control the vaporizing speed at a proper value is not an easy job.

Accordingly, the invention discloses a metal pattern formation method and a metal pattern formation system capable of properly adjusting the heating process to cooperate with different organic liquids with different vaporizing speeds. For this reason, it requires controlling the vaporizing speeds no more, and consequently lowers the producing difficulty, so as to solve said problems.

### SUMMARY OF THE INVENTION

A scope of the invention is to provide a metal pattern formation method, which prevents an organic liquid from being left on a substrate after a metal evaporation.

To achieve the scope, the metal pattern formation method comprises following steps of: 1) printing an organic liquid onto a substrate to form a base pattern; 2) evaporating a metal to generate a plurality of metal particles, the plurality of metal particles being used for covering the printed substrate; and 3) heating the substrate to vaporize the base pattern, the plurality of metal particles adhered on the substrate forming a metal pattern complementary to the base pattern.

Another scope of the invention is to provide a metal pattern formation system, which prevents an organic liquid from being left on a substrate after a metal evaporation.

To achieve the scope, the metal pattern formation system comprises a substrate, a printing device, an evaporating device and a heating device. The printing device prints an organic liquid onto the substrate to form a base pattern. The evaporating device evaporates a metal to generate a plurality of metal particles. The plurality of metal particles is used for covering the printed substrate. The heating device heats the substrate to vaporize the base pattern. The plurality of metal particles adhered on the substrate forms a metal pattern complementary to the base pattern.

In summary, corresponding to organic liquids with different vaporizing speeds, it needs only to select proper heating temperature and heating time in the invention, and it can prevent the organic liquids from being left on the substrate after the metal evaporation. In other words, the metal pattern formation method and a metal pattern formation system of the invention utilizes the heating process to vaporize the organic liquid left on the substrate after the metal evaporation, so as to prevent the organic liquid left from reacting with the substrate. The invention can effectively deal with the swelling reaction caused by the low-vaporizing speed organic liquid left on the substrate. At the same time, the invention with the heating device may select any organic liquids with lower vaporizing speeds. Therefore, it has less limitation about the organic liquid, so as to broaden the application of the metal pattern formation system of the invention.

The advantage and spirit of the invention may be understood by the following recitations together with the appended drawings.

### BRIEF DESCRIPTION OF THE APPENDED DRAWINGS

FIG. 1 is a schematic diagram illustrating a metal pattern formation system according to an embodiment of the invention.

FIG. 2 is a flowchart illustrating a metal pattern formation method according to an embodiment of the invention.

FIG. 3 is an enlarged vertical view illustrating a polycarbonate (PC) substrate with 4-fluoroanisole printed after a metal evaporation.

FIG. 4 is an enlarged vertical view illustrating a polycarbonate substrate with 3-fluorobenzoitrile printed after a metal evaporation.

FIG. 5 is an enlarged vertical view illustrating an acrylonitrile butadiene styrene (ABS) substrate with isopropanol printed after a metal evaporation.

### DETAILED DESCRIPTION OF THE INVENTION

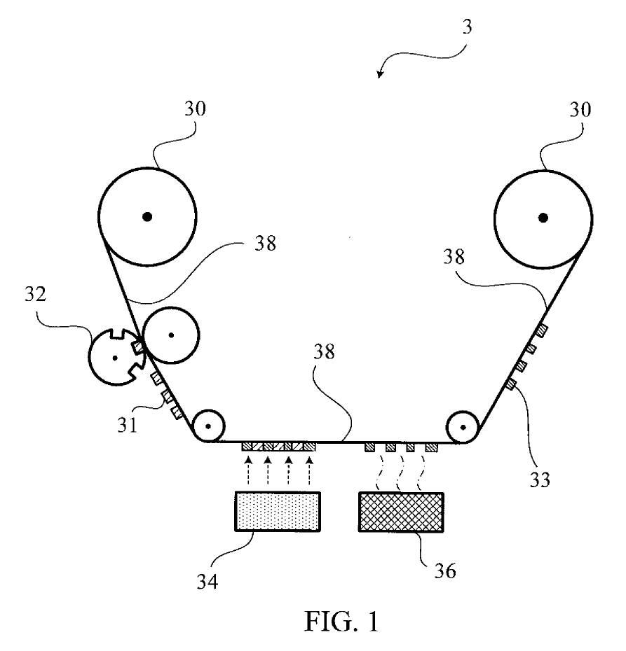

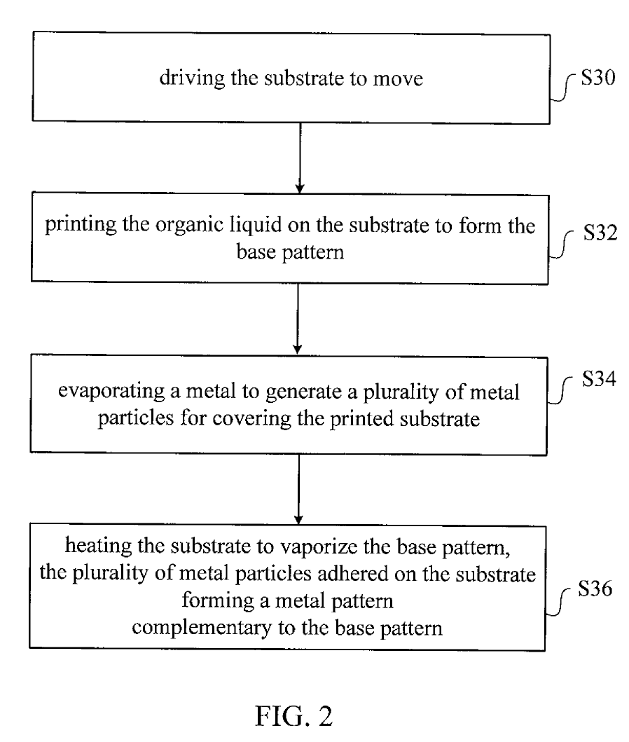

Please refer to FIG. 1 and FIG. 2. FIG. 1 is a schematic diagram illustrating a metal pattern formation system 3 according to an embodiment of the invention. FIG. 2 is a flowchart illustrating a metal pattern formation method according to an embodiment of the invention. As shown in FIG. 1, the metal pattern formation system 3 comprises a driving device 30, substrate 38, a printing device 32, an evaporating device 34 and a heating device 36. In order to reduce the environmental interference in the metal pattern formation system 3 to the least degree, the metal pattern formation system 3 may further comprise a vacuum chamber (not shown), in which driving device 30, substrate 38, a printing device 32, an evaporating device 34 and a heating device 36 are disposed, for quarantining the environmental interference and controlling the environmental index (e.g. temperature, pressure). The details about the metal pattern formation system 3 in FIG. 1 to execute the flow of the metal pattern formation method in FIG. 2 are disclosed as follows.

Firstly, step S30 is executed to activate the driving device 30 for driving the substrate 38 to move. The driving device 30 is a pair of rollers. One roller in FIG. 1 is used for pushing the substrate 38, while the other roller is used for pulling the substrate 38.

Afterward, step S32 is executed to activate the printed device 32 for printing an organic liquid onto the moving substrate 38 to form a base pattern 31.

Afterward, step S34 is executed to activate the evaporating device 34 for evaporating a metal to generate a plurality of metal particles. The plurality of metal particles is used for covering the printed substrate 38.

Finally, step S36 is executed to activate the heating device 36 for heating the substrate 38 to vaporize the base pattern 31, the plurality of metal particles adhered on the substrate 38 forming a metal pattern 33 complementary to the base pattern 31.

The organic liquid is used for blocking the metal particle from adhering onto the substrate, and has a shielding function. The vaporizing speed of the organic liquid is going to be sped up because the environmental temperature of the metal evaporation is high. Accordingly, the invention adopt the organic liquid with slow vaporizing speed, for ensuring that the organic liquid would not over-vaporized and maintain the shielding effect, so as to ensure the preciseness of the metal pattern.

However, the organic liquid with slow vaporizing speed is easy to be left on the substrate and react with the substrate. The organic liquid left may induce the swelling effect on the substrate with the substrate and affect the quality of product. Aimed at this disadvantage, the invention utilizes the heating device actively rise the temperature of the substrate for vaporizing the organic liquid left on the substrate after the metal evaporation. The heating device can be a resistor heating device (thermal conduction) or an infrared heating device (thermal radiation). The invention may select any organic liquid with lower vaporizing speed, and then manage the heating temperature and the heating time of the heating device properly, for producing the metal pattern precisely without taking care of the vaporizing speed of the organic liquid too much.

In the embodiment shown in FIG. 1, the printing device 32 prints the organic liquid onto the substrate 38 in a way of gravure, but not limited to it. The organic liquid of the invention can also be printed in a way of lithography, letterpress, flexography, screen printing or ink-jet printing.

In the embodiment, a material of the substrate is polycarbonate (PC). The material of the substrate may also be polyethylene (PE), polyethylene terephthlate (PET), polypropylene (PP), polyimide (PI), acrylonitrile butadiene styrene (ABS), or some other plastic. Besides, the metal which is evaporated by the evaporating device 34 can be aluminum, tin, indium, titanium, copper, silver, nickel, cobalt, zinc or a compound thereof (e.g. aluminum-titanium compound). Surely, the metal used to cover the printed substrate is not limited to a singular metal, but it can be multiple layers of different metals, for increasing the variety or fret-durability and etch-durability of the metal pattern.

In order to increase the adhesive strength between the metal particles and the substrate, it can perform a pre-process on the substrate for generating free radical. The free radical helps the substrate attract the metal particles. In another way, it can heat the substrate to vapor the water steam on the substrate, while it is easier for the dry substrate to attract the metal particle.

The vaporizing speed of the organic liquid is measured by the weight variation in 30 minutes under the same temperature and pressure, and is represented in a scalar of milligram per centimeter square per hour (mg/h, cm²). There are three organic liquids of the invention, which are 2-fluorobenzaldehyde, 4-fluoroanisole and 3-fluorobenzonitrile, listed in Table 1.

TABLE 1

| | Vaporizing speed |
|---|---|
| Organic liquid | (mg/h, cm²) |
| 2-fluorobenzaldehyde | 1.41 |
| 4-fluoroanisole | 5.23 |
| 3-fluorobenzonitrile | 2.21 |

As shown in Table 1, compared with the vaporizing speed of ethanol (138.2 mg/h,cm²), the vaporizing speeds of 4-fluoroanisole and 3-fluorobenzonitrile are 5.23 mg/h,cm² and 2.21 mg/h,cm ² respectively, and are classified as slow vaporizing speeds. For this reason, those organic liquids are adopted in the invention.

Besides, the contact angle is the angle at which a liquid interface meets the solid surface when 1 μL of liquid are dropped on the substrate. A smaller contact angle is related to a weaker surface tension of the organic liquid. The surface tension is something about the adhering strength between the liquid and the substrate. If the surface tension of the liquid is lower than the surface tension of the substrate, it will be easy for the liquid to attach onto the substrate. Three contact angles of the three organic liquids of the invention, which are 2-fluorobenzaldehyde, 4-fluoroanisole and 3-fluorobenzonitrile, are listed in Table 2.

TABLE 2

| Organic liquid | Contact angle |
|---|---|
| 2-fluorobenzaldehyde | 26° |
| 4-fluoroanisole | 30° |
| 3-fluorobenzonitrile | 23° |

The contact angle of ethanol on a plastic substrate (45°) is usually regarded as the judging standard of whether the organic liquid can attach onto the substrate. If the contact angle of a liquid on the plastic substrate is smaller than 45°, it means that the liquid can attach onto the plastic substrate. As shown in Table 2, the contact angles of 2-fluorobenzaldehyde, 4-fluoroanisole and 3-fluorobenzonitrile are 26°, 30° and 23°, all of which are below 45°. For this reason, those organic liquids may attach onto the substrate easily.

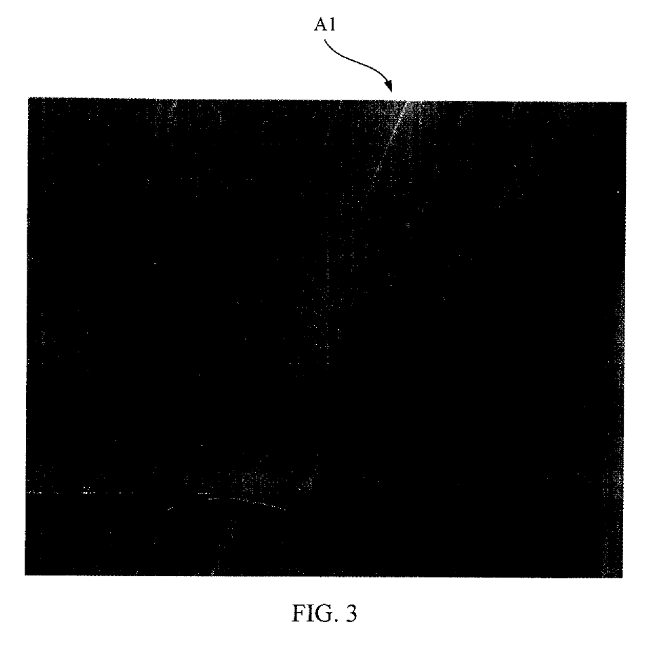

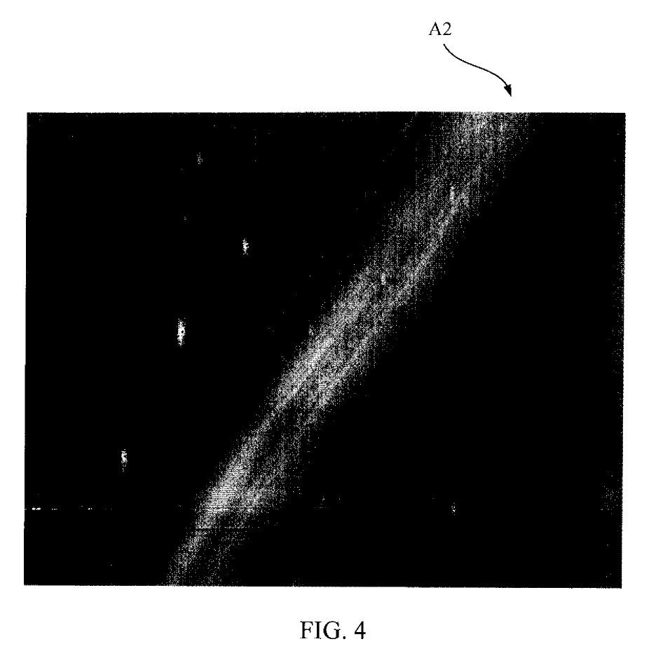

Please refer to FIG. 3 and FIG. 4. FIG. 3 and FIG. 4 are shot by an optical microscope (model spec. Olympus SZ-PT) under the magnification of 115 times. FIG. 3 is an enlarged vertical view illustrating a polycarbonate (PC) substrate with 4-fluoroanisole printed after a metal evaporation. FIG. 4 is an enlarged vertical view illustrating a polycarbonate substrate with 3-fluorobenzoitrile printed after a metal evaporation. The tube-shaped region A1 in FIG. 3 with 0.15 mm width (eq. 167 lines per inch (lpi)) and the tube-shaped region A2 in FIG. 4 with 0.19 mm width (eq. 136 lines per inch (lpi)) are both adhere-free region to the aluminum particles. Therefore, 4-fluoroanisole and 3-fluorobenzonitrile may effectively block the metal particles from adhering onto the PC substrate. Consequently, a material of the substrate can be polycarbonate, and the organic liquid can be 4-fluoroanisole or 3-fluorobenzonitrile.

In this reason, as shown in Table 1 and Table 2, the vaporizing speed of 2-fluorobenzaldehyde is lower than the vaporizing speed of 4-fluoroanisole or 3-fluorobenzonitrile. At the same time, the contact angles of 2-fluorobenzaldehyde (26°) is smaller than the one of 4-fluoroanisole. Therefore, 2-fluorobenzaldehyde may effectively block the metal particles from adhering onto the PC substrate. Consequently, the organic liquid can be 2-fluorobenzaldehyde while the material of the substrate is polycarbonate.

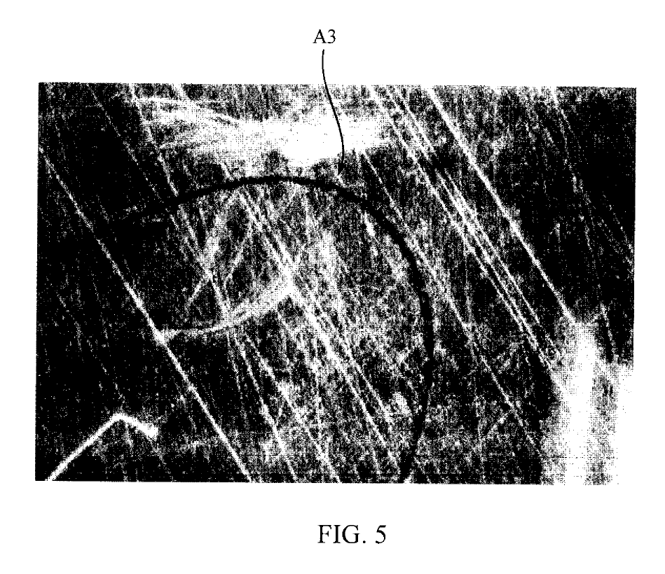

Furthermore, the contact angle of isopropanol on the ABS susbstrate is 19°, so that isopropanol can attach onto the ABS substrate easily. Although the vaporizing speed of isopropanol is higher than one of 2-fluorobenzaldehyde, 4-fluoroanisole or 3-fluorobenzonitrile, but it is lower than the vaporizing speed of ethanol. Please refer to FIG. 5. FIG. 5 is also shot by the optical microscope (model spec. Olympus SZ-PT). FIG. 5 is an enlarged vertical view illustrating an acrylonitrile butadiene styrene (ABS) substrate with isopropanol printed after a metal evaporation. The curve-shaped region A3 in FIG. 5 on the ABS substrate is adhere-free region to the aluminum particles. Therefore, isopropanol may obviously block the metal particles from adhering onto the ABS substrate. Consequently, the organic liquid for printing of the invention can be isopropanol while the material of the substrate is acrylonitrile butadiene styrene.

Additionally, in the embodiment, the moving speed of the substrate is around 60˜100 cm/minute. The heating temperature is around 80° C. (<100° C.). The distance between the heating device and the substrate is around 1 cm. The moving speed, heating temperature and the distance are related to each others, and not limited to particular values. For example, to boost the producing speed, it may speed up the moving speed of the substrate. At the same time, it may correspondingly rise the heating temperature properly and even shorten the distance between the heating device and the substrate properly. In this way, when an index is changed, the vaporizing speed can be maintained by modifying the other two indices, to achieve the same quality of the metal pattern.

Compared with the prior art, corresponding to organic liquids with different vaporizing speeds, it needs only to select proper heating temperature and heating time in the invention, and it can prevent the organic liquids from being left on the substrate after the metal evaporation. In other words, the metal pattern formation method and a metal pattern formation system of the invention utilizes the heating process to vaporize the organic liquid left on the substrate after the metal evaporation, so as to prevent the organic liquid left from reacting with the substrate. The invention can effectively deal with the swelling reaction caused by the low-vaporizing speed organic liquid left on the substrate. At the same time, the invention with the heating device may select any organic liquids with lower vaporizing speeds. Therefore, it has less limitation about the organic liquid, so as to broaden the application of the metal pattern formation system of the invention.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A metal pattern formation method, comprising steps of:
printing an organic liquid onto a substrate to form a base pattern;
evaporating a metal to generate a plurality of metal particles, the plurality of metal particles being used for covering the printed substrate; and
heating the substrate to vaporize the base pattern, the plurality of metal particles adhered on the substrate forming a metal pattern complementary to the base pattern.

2. The metal pattern formation method of claim 1 being performed within a vacuum chamber.

3. The metal pattern formation method of claim 1, the step of printing the organic liquid comprising steps of:
driving the substrate to move; and
printing the organic liquid on the moving substrate to form the base pattern.

4. The metal pattern formation method of claim 1, wherein the substrate is heated with a resistor or by an infrared.

5. The metal pattern formation method of claim 1, wherein the organic liquid is printed on the substrate in a way of lithography, letterpress, flexography, gravure, screen printing or ink-jet printing.

6. The metal pattern formation method of claim 1, wherein the metal is one selected from the group consisting of aluminum, tin, indium, titanium, copper, silver, nickel, cobalt, zinc and a compound thereof.

7. The metal pattern formation method of claim 1, wherein a material of the substrate is polycarbonate, and the organic liquid is 2-fluorobenzaldehyde, 4-fluoroanisole or 3-fluorobenzonitrile.

8. The metal pattern formation method of claim 1, wherein a material of the substrate is acrylonitrile butadiene styrene, and the organic liquid is isopropanol.

9. A metal pattern formation system, comprising:
a substrate;
a printing device, for printing an organic liquid onto the substrate to form a base pattern;
an evaporating device, for evaporating a metal to generate a plurality of metal particles, the plurality of metal particles being used for covering the printed substrate; and
a heating device, for heating the substrate to vaporize the base pattern, the plurality of metal particles adhered on the substrate forming a metal pattern complementary to the base pattern.

10. The metal pattern formation system of claim 9, further comprising a vacuum chamber for accommodating the substrate, the printing device, the evaporating device and the heating device.

11. The metal pattern formation system of claim 9, further comprising a driving device for driving the substrate to move, the printing device printing the organic liquid on the moving substrate.

12. The metal pattern formation system of claim 9, wherein the heating device is an infrared heating device or a resistor heating device.

13. The metal pattern formation system of claim 9, wherein the printing device prints the organic liquid on the substrate in a way of lithography, letterpress, flexography, gravure, screen printing or ink-jet printing.

14. The metal pattern formation system of claim 9, wherein the metal is one selected from the group consisting of aluminum, tin, indium, titanium, copper, silver, nickel, cobalt, zinc and a compound thereof.

15. The metal pattern formation system of claim 9, wherein a material of the substrate is polycarbonate, and the organic liquid is 2-fluorobenzaldehyde, 4-fluoroanisole or 3-fluorobenzonitrile.

16. The metal pattern formation system of claim 9, wherein a material of the substrate is acrylonitrile butadiene styrene, and the organic liquid is isopropanol.
